(19) United States
(12) Patent Application Publication
(10) Pub. No.: US 2012/0228653 A1
(43) Pub. Date: Sep. 13, 2012

(54) LIGHT EMITTING DEVICE

(75) Inventors: Kunio ISHIDA, Tokyo (JP); Iwao Mitsuishi, Tokyo (JP); Shinya Nunoue, Chiba (JP)

(73) Assignee: KABUSHIKI KAISHA TOSHIBA, Tokyo (JP)

(21) Appl. No.: 13/215,659

(22) Filed: Aug. 23, 2011

(30) Foreign Application Priority Data
Mar. 8, 2011 (JP) 2011-050012

(51) Int. Cl. H01L 33/50

(52) U.S. Cl. 257/98; 257/E33.061

(57) ABSTRACT

A light emitting device of embodiments is provided with a light-emitting element emitting excitation light of a first wavelength, a first phosphor layer containing a first phosphor that converts the excitation light into first converted light of a second wavelength longer than the first wavelength, a second phosphor layer provided between the light-emitting element and the first phosphor layer, receiving the excitation light, and containing a second phosphor that converts the excitation light into second converted light of a third wavelength longer than the second wavelength, and a filter layer provided between the first phosphor layer and the second phosphor layer and constituted of a two-dimensional photonic crystal or a three-dimensional photonic crystal that transmits the excitation light and the second converted light and reflects the first converted light.

### CROSS-REFERENCE TO RELATED APPLICATION

This application is based upon and claims the benefit of priority from Japanese Patent Application No. 2011-50012, filed on Mar. 8, 2011, the entire contents of which are incorporated herein by reference.

### FIELD

Embodiments described herein relate generally to a light emitting device.

### BACKGROUND

Recently, a so-called white light emitting diode (LED) that is obtained by combining a yellow phosphor such as YAG:Ce with a blue LED and emits white light by a single chip has attracted attention. Conventionally, an LED emits light of single color of red, green, and blue. In order to emit white light or light of intermediate color, a plurality of LEDs emitting a single color wavelength should be used and individually driven. However, presently, a light emitting diode and a phosphor are combined with each other, whereby the above burden is removed, and white light can be obtained by a simple structure.

An LED lamp using the light emitting diode is used in various display devices including a portable device, PC peripheral equipment, OA equipment, various switches, a light source for backlight, and a display board. The efficiency of those LED lamps are strongly expected to be increased. In addition, high color rendering is required to be realized for use in general illumination, and high color gamut is required to be realized for use in backlight. In order to realize high efficiency, the efficiency of a phosphor is required to be increased. In order to realize high color rendering or high color gamut, it is preferable to provide a white light source in which blue excitation light, a phosphor excited by blue and exhibiting green light emission, and a phosphor excited by blue and exhibiting red light emission are combined.

When a plurality of phosphors are used, there is a problem that the light emitting efficiency is reduced by reabsorption between the phosphors. Especially, when white light is to be obtained by combining a plurality of phosphors on one LED chip, the phosphors approach each other, whereby the problem becomes obvious.

In order to solve the above problem, there has been proposed a technique of providing a filter layer formed of a dielectric multilayer film between one phosphor and the other phosphor and suppressing the reabsorption between the phosphors (JP 2007-142268A (Kokai)).

The dielectric multilayer film is constituted based on a principle that wavelength dependency of reflectance and transmittance is obtained by interference of light transmitted through or reflected from a dielectric film with regulated thickness. Accordingly, by its nature, there has been known that the reflectance and the transmittance are different depending on the incident angle of light entering the filter layer.

Thus, in the filter layer using the dielectric multilayer film, a sufficient effect of suppressing the reabsorption may not always be obtained. Especially, when the chip size of a light emitting element is increased, the range of the light incident angle to the filter layer is increased, and therefore, there is concern that the sufficient reabsorption suppressive effect cannot be obtained.

### BRIEF DESCRIPTION OF THE DRAWINGS

FIG. 1 is a schematic cross-sectional view of a light emitting device of a first embodiment;

FIG. 2 is a view showing an example of a structure of a photonic crystal of the first embodiment;

FIG. 3 is a view showing an example of the structure of the photonic crystal of the first embodiment;

FIG. 4 is a view for illustrating operation of the light emitting device of the first embodiment;

FIG. 5 is a view for illustrating the operation of the light emitting device of the first embodiment;

FIG. 6 is a cross-sectional process view showing a method of manufacturing the light emitting device of the first embodiment;

FIG. 7 is a cross-sectional process view showing the method of manufacturing the light emitting device of the first embodiment; and

FIG. 8 is a schematic cross-sectional view of a light emitting device of a second embodiment.

### DETAILED DESCRIPTION

Alight emitting device of embodiments is provided with a light emitting element emitting excitation light of a first wavelength, a first phosphor layer containing a first phosphor that converts the excitation light into first converted light of a second wavelength longer than the first wavelength, a second phosphor layer provided between the light-emitting element and the first phosphor layer, receiving the incidence of the excitation light, and containing a second phosphor that converts the excitation light into second converted light of a third wavelength longer than the second wavelength, and a filter layer provided between the first phosphor layer and the second phosphor layer and constituted of a two-dimensional photonic crystal or a three-dimensional photonic crystal that transmits the excitation light and the second converted light therethrough and reflects the first converted light therefrom.

Hereinafter, embodiments will be described using the drawings. In the drawings, the same or similar components are denoted by the same or similar reference numerals.

In the specification, “near-ultraviolet light” means light of wavelength of 250 nm to 410 nm. “Blue light” means light of wavelength of 410 nm to 500 nm. “Green light” means light of wavelength of 500 nm to 580 nm. “Red light” means light of wavelength of 595 nm to 700 nm.

“Red phosphor” means a phosphor exhibiting light of wavelength of 250 nm to 500 nm, that is, light emission that has a wavelength longer than the excitation light when excited by the near-ultraviolet light or the blue light and is in a region from orange to red, that is, light emission having a main light emitting peak within a wavelength range of 595 nm to 700 nm.

In the specification, a “green phosphor” means a phosphor exhibiting light of wavelength of 250 nm to 500 nm, that is, light emission that has a wavelength longer than the excitation light when excited by the near-ultraviolet light or the blue light and is in a region from blue green to yellow green, that is, light emission having a main light emitting peak within a wavelength range of 490 nm to 580 nm.

In the specification, the “photonic crystal” means a “periodic structure of refractive index (permittivity)”. The structure in which the permittivity changes periodically with a period near the wavelength of light is artificially created, whereby light propagation in the structure can be controlled.

In the specification, “the filter layer transmits light therethrough” means that the transmittance of light to the filter layer is larger than the reflectance. In the specification, “the filter layer reflects light therefrom” means that the reflectance of light to the filter layer is larger than the transmittance.

### First Embodiment

A light emitting device of the present embodiment is provided with a light-emitting element emitting excitation light of a first wavelength, a first phosphor layer receiving the incidence of the excitation light and containing a first phosphor that converts the excitation light into first converted light of a second wavelength longer than the first wavelength, a second phosphor layer provided between the light-emitting element and the first phosphor layer, receiving the incidence of the excitation light, and containing a second phosphor that converts the excitation light into second converted light of a third wavelength longer than the second wavelength, and a filter layer provided between the first phosphor layer and the second phosphor layer and constituted of a two-dimensional photonic crystal or a three-dimensional photonic crystal that transmits the excitation light and the second converted light therethrough and reflects the first converted light therefrom.

The light emitting device of the present embodiment comprises the above constitution, whereby among green light emitted from a green phosphor, light traveling toward a red phosphor is reflected by the filter layer. According to this constitution, the reabsorption of the green light by the red phosphor is suppressed. Accordingly, a light emitting device that realizes excellent light emitting efficiency can be realized.

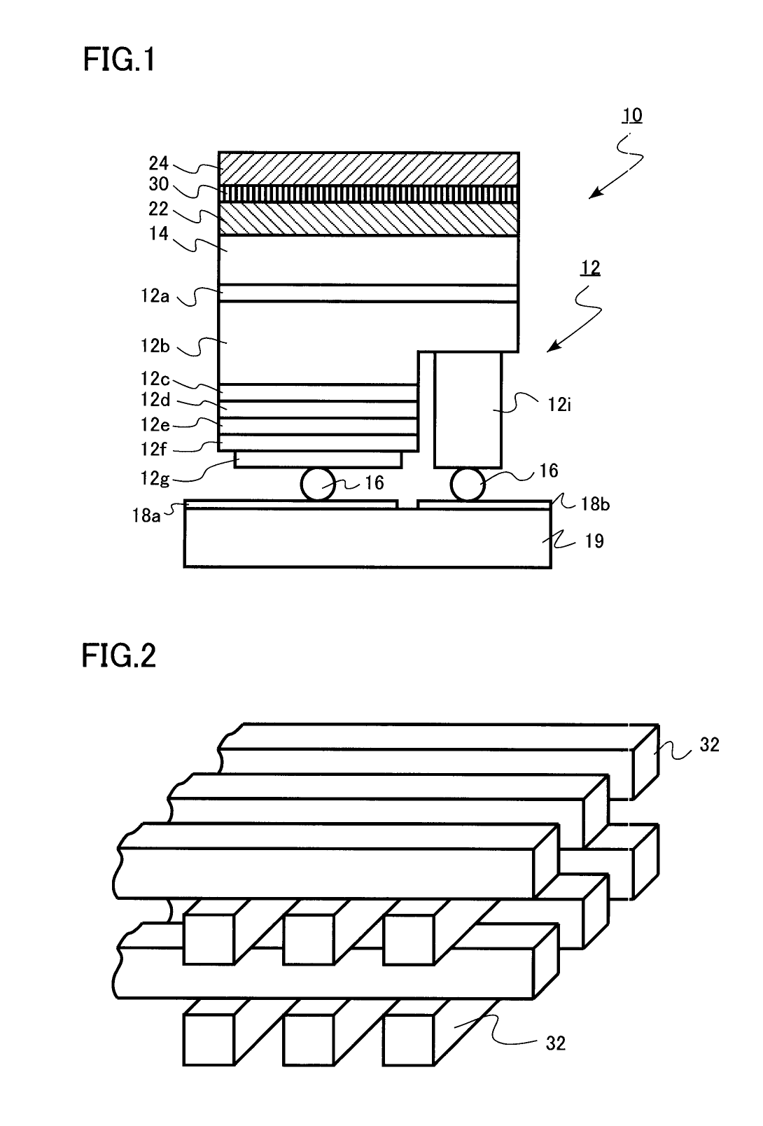

FIG. 1 is a schematic cross-sectional view of a light emitting device of the present embodiment. FIG. 1 shows a state in which the light emitting device of the present embodiment is mounted on a mounting substrate.

A light emitting device 10 of the present embodiment is provided with a substrate 19 and a light emitting element 12 for an excitation light source mounted on the substrate 19. The light emitting element 12 for an excitation light source is, for example, a blue LED chip emitting blue light (excitation light of a first wavelength) having a peak wavelength of 450 nm. The blue LED chip has an upper surface having a rectangular shape whose one side is approximately 300 to 600 μm, for example, a square upper surface.

The light emitting element 12 has on its upper surface a transparent medium layer 14, for example. The transparent medium layer 14 is, for example, a sapphire substrate for use in the formation of the light emitting element 12.

When viewed from the upper side of FIG. 1, for example, a blue LED has a laminated structure of a buffer layer 12a formed to be in contact with the sapphire substrate 14, an n-type GaN layer 12b, an n-type AlGaN layer 12c, an InGaN-based active layer 12d, a p-type AlGaN layer 12e, and a p-type GaN layer 12f stacked in this order. A p-side electrode 12g is provided to be in contact with the p-type GaN layer 12f.

An n-side electrode 12i is provided to be in contact with the n-type GaN layer 12b in a region where a portion of the laminated structure of the p-type GaN layer 12f, the p-type AlGaN layer 12e, the InGaN-based active layer 12d, the n-type AlGaN layer 12c, and the n-type GaN layer 12b is removed by etching.

The blue LED chip has a flip chip configuration in which the p-side electrode 12g and the n-side electrode 12i are placed on a metallization mounting substrate 19, having on its surface wiring layers 18a and 18b formed of metal, through bumps 16 formed of Au (gold), for example.

The light emitting device 10 of the present embodiment is provided with a green phosphor layer (first phosphor layer) 24 and a red phosphor layer (second phosphor layer) 22 provided between the light emitting element 12 and the green phosphor layer (first phosphor layer) 24. Further, a filter layer 30 is provided between the green phosphor layer (first phosphor layer) 24 and the red phosphor layer (second phosphor layer) 22. Namely, the red phosphor layer (second phosphor layer) 22, the filter layer 30, and the green phosphor layer (first phosphor layer) 24 are stacked in this order on the sapphire substrate 14.

The green phosphor layer (first phosphor layer) 24 receives the incidence of the blue light as the excitation light and contains a green phosphor (first phosphor) that converts the blue light into green light (first converted light) of a wavelength longer than that of the blue light. For example, particles of the green phosphor are dispersed into a transparent resin layer such as a silicone resin to form the green phosphor layer.

The red phosphor layer (second phosphor layer) 22 receives the incidence of the blue light as the excitation light and contains a red phosphor (second phosphor) that converts the blue light into red light (second converted light) of a wavelength longer than that of the blue light. For example, particles of the red phosphor are dispersed into a transparent resin layer such as a silicone resin to form the red phosphor layer.

The filter layer 30 is constituted of a two-dimensional photonic crystal or a three-dimensional photonic crystal. The filter layer 30 has a function of transmitting the blue light (excitation light) as the excitation light and the red light (second converted light) therethrough and reflecting the green light (first converted light) therefrom.

For example, the filter layer 30 transmits therethrough light of a wavelength less than 450 nm or more than 580 nm and reflects therefrom light of a wavelength of 450 nm to 580 nm. Namely, the filter layer 30 has a bandgap of 450 nm to 580 nm. The bandgap is a wavelength range of light that does not transmit through (or reflects from) the filter layer (photonic crystal).

The filter layer 30 has isotropy with respect to the transmittance and the reflectance to light. Namely, even if the incident angle of light entering the filter layer is changed, the transmittance and the reflectance to the light are substantially constant.

In terms of improving the light emitting efficiency, it is preferable that the reflectance of the green light (first converted light) is not less than 90%, and the transmittance of the blue light (excitation light) and the red light (second converted light) is not less than 90%.

FIG. 2 is a view showing an example of a structure of a photonic crystal of the present embodiment. The photonic crystal of FIG. 2 has a woodpile structure in which layers each constituted of a plurality of stripes 32 are stacked so that the stripes 32 are rotated by 90 degrees for each layer. The stripe is silicon (Si), for example.

For example, one silicon stripe has a width of 0.6 μm and a thickness of 1.1 μm, and the period of the stripe is 2.4 μm. The ten stripe layers are stacked to form the photonic crystal. For example, the photonic crystal cut into squares whose side is 285 μm is used as the filter layer 30. According to the above structure, the filter layer 30 has a bandgap of 470 nm to 550 nm.

It is preferable that the two-dimensional photonic crystal and the three-dimensional photonic crystal have the woodpile structure, a Yablonovitch structure, or a face-centered cubic lattice structure in terms of providing excellent isotropy with respect to the transmittance and the reflectance to light.

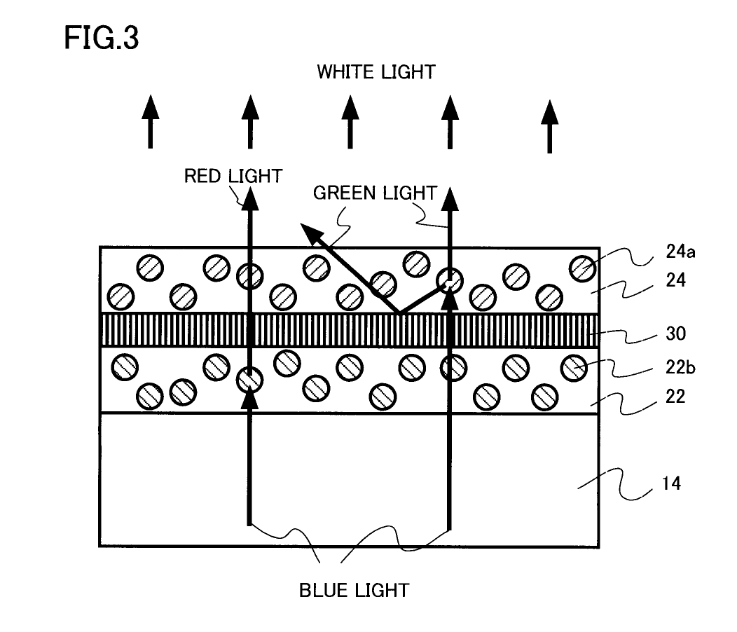

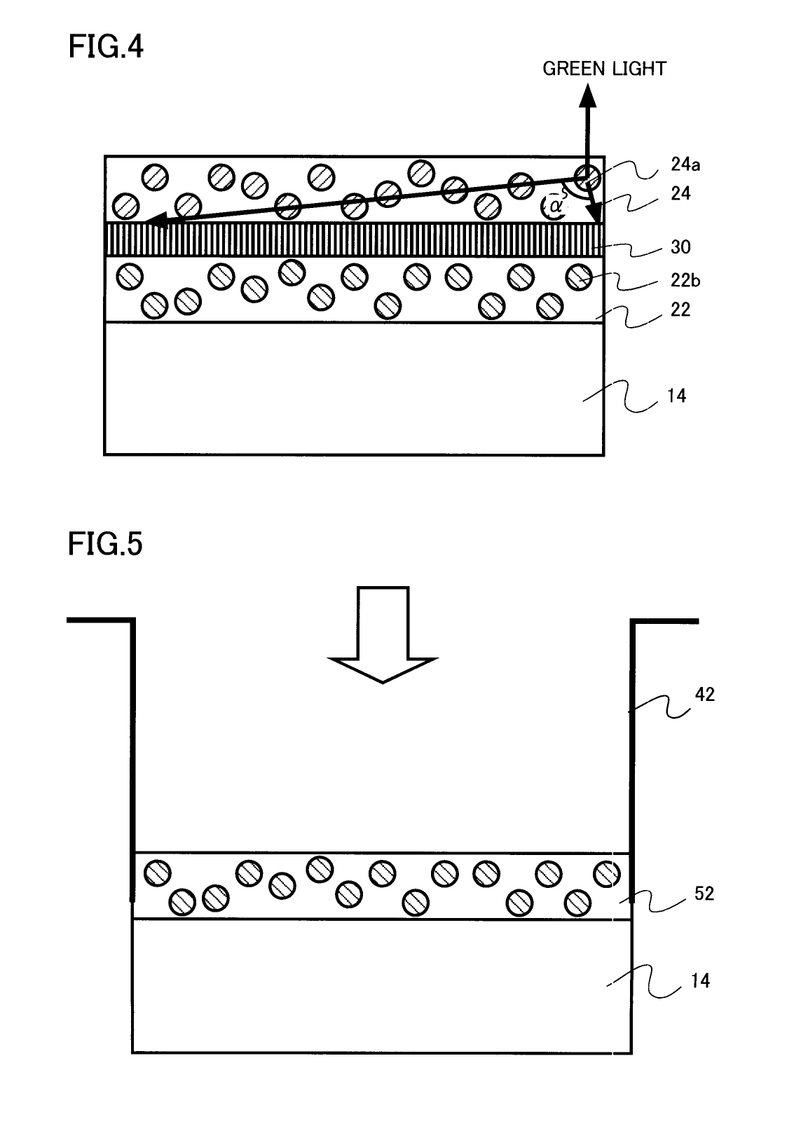

FIGS. 3 and 4 are views for illustrating the operation of the light emitting device of the present embodiment. As shown in FIG. 3, the blue light as the excitation light enters the red phosphor layer 22 to be converted into the red light by a red phosphor 22b. Further, the blue light enters the green phosphor layer 24 to be converted into the green light by a green phosphor 24b. Those blue light, red light, and green light are mixed to become white light.

At that time, among the green light emitted from the green phosphor 24b, the green light traveling toward the red phosphor layer 22 is generated. When the green light is reabsorbed by the red phosphor 22b in the red phosphor layer 22, the light emitting efficiency of the light emitting device is reduced.

In the present embodiment, the filter layer 30 uses the two-dimensional photonic crystal or the three-dimensional photonic crystal excellent in isotropy of the transmittance and the reflectance in comparison with a dielectric multilayer film, for example. Accordingly, even when the green light traveling toward the red phosphor layer 22 enters at a different angle, the green light is effectively reflected, whereby the green light is suppressed from entering the red phosphor layer 22. Consequently, the light emitting device that suppresses the reabsorption between the phosphors and realizes the excellent light emitting efficiency can be provided.

In particular, in order to realize a high output of the light emitting device, when the chip size of the light emitting element 12 increases, the light emitting device of the present embodiment is effective. This is because when the chip size increases, for the green light traveling from the green phosphor layer 24 toward the red phosphor layer 22, a range (α in FIG. 4) of the incident angle to the filter layer 30 increases inevitably.

In the present embodiment, as the red phosphor and the green phosphor, a so-called sialon-based phosphor is used. In the sialon-based phosphor, since reduction in the light emitting efficiency at high temperature, so-called temperature quenching, is small, color shift is small, so that the sialon-based phosphor is suitable for realizing high-density packaging and high output light emitting device.

The red phosphor of the present embodiment has the following composition (formula 1), for example.

(M₁₋ₓ₁Euₓ₁)ₐSi_{b}AlO_{c}N_{d} (1)

In the above formula (1), M is an element selected from a group IA element, a group IIA element, a group IIIA element, a group IIIB element except for Al, a rare-earth element, and a group IVB element. x1, a, b, c, and d satisfy the following relationship:

0<x1<1

0.55<a<0.95

2.0<b<3.9

0<c<0.6

4<d<5.7

When M is Sr (strontium), the absorption intensity of the green light is especially high, and thus, the present embodiment is effective and preferable. However, the red phosphor is not limited thereto and may be CaAlSiN₃:Eu, CaS:Eu, (Ba,Sr,Ca)₂Si₅N₈:Eu, 3.5MgO•0.5MgF₂•GeO₂:Mn, K₂SiF₆:Mn, or Y₂O₃:Eu.

The green phosphor of the present embodiment has the following composition (formula 2), for example.

(M′₁₋ₓ₂Euₓ₂)_{3-y}Si_{13-z}Al_{3+z}O₂₊ᵤN_{21-w} (2)

In the above formula (2), M′ is an element selected from a group IA element, a group IIA element, a group IIIA element, a group IIIB element except for Al, a rare-earth element, and a group IVB element. x2, y, z, u, and w satisfy the following relationship:

0<x2<1

−0.1<y<0.3

−3<z≦1

−3<u−w≦1.5

It is preferable that M′ is Sr (strontium). However, the green phosphor is not limited thereto and may be a β sialon phosphor or a YAG:Ce phosphor.

FIGS. 5 to 7 are cross-sectional process views showing a method of manufacturing the light emitting device of the present embodiment.

The light emitting element 12 is formed on the sapphire substrate 14. The chip size of the light emitting element is 300 μm.

Next, the sapphire substrate 14 is covered by a metal mask 42, and a resin 52 in which the red phosphor is dispersed is coated from the above of the metal mask 42 (FIG. 5). At that time, the size of an opening of the metal mask 42 is 290 μm relative to the chip size of 300 μm and, at the same time, the viscosity of the resin is adjusted, whereby the resin can be coated.

After that, the metal mask 42 is removed, and the resin is left for 30 minutes under the temperature of 150° C., whereby the resin is cured. In this way, the red phosphor layer 22 with a thickness of 50 μm, for example is formed on the sapphire substrate 14.

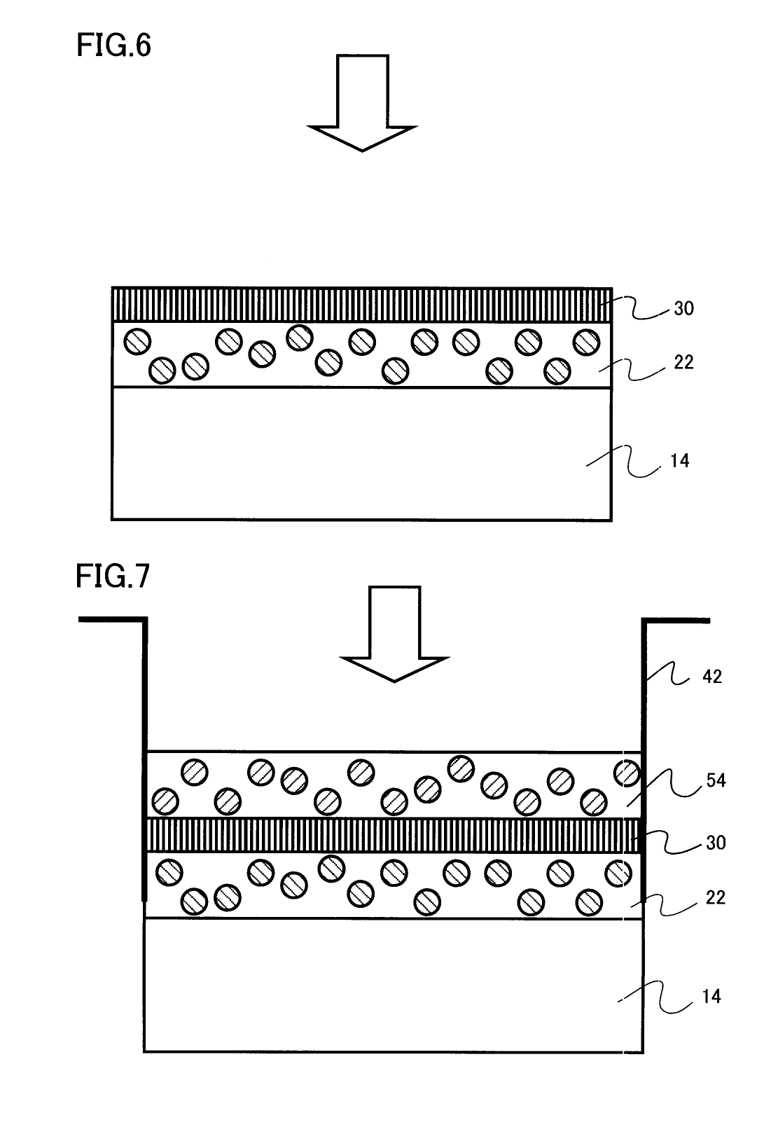

After that, the filter layer 30 constituted of the two-dimensional photonic crystal or the three-dimensional photonic crystal is provided so as to be adhered firmly to the red phosphor layer 22 (FIG. 6). The photonic crystal of the filter layer 30 is, for example, a photonic crystal of 285 μm having the woodpile structure that has been described using FIG. 2. The photonic crystal having the woodpile structure can be formed using a so-called wafer fusion method.

Next, the sapphire substrate 14 is covered by the metal mask 42 again, and a resin 54 in which the green phosphor is dispersed is coated from the above of the metal mask 42 (FIG. 7). At that time, the size of an opening of the metal mask 42 is 290 μm relative to the chip size of 300 μm, and, at the same time, the viscosity of the resin is adjusted, whereby the resin can be coated.

After that, the metal mask 42 is removed, and the resin is left for 30 minutes under the temperature of 150° C., whereby the resin is cured. In this way, the green phosphor layer 24 with a thickness of 50 μm, for example is formed on the filter layer 30.

According to the above method, the light emitting device shown in FIG. 1 is manufactured.

### Second Embodiment

The light emitting device of the present embodiment is different from the first embodiment in that the light emitting element is a near-ultraviolet LED chip emitting near-ultraviolet light and the light emitting device has a blue phosphor layer. Hereinafter, the description of the contents overlapped with those of the first embodiment is omitted.

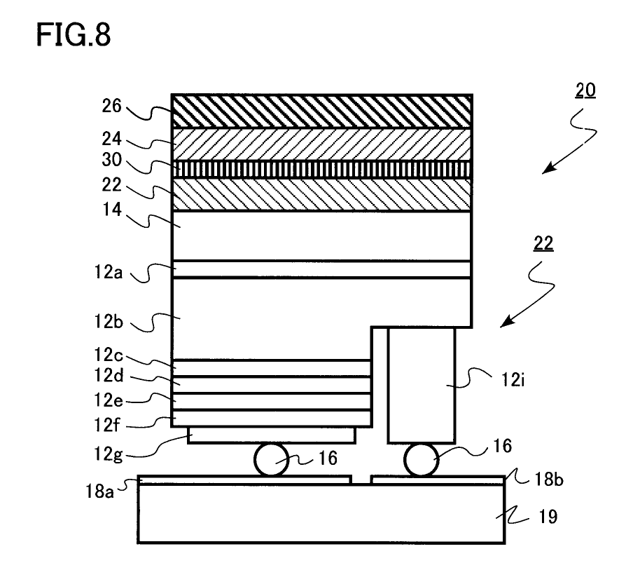

FIG. 8 is a schematic cross-sectional view of a light emitting device of the present embodiment. FIG. 8 shows a state in which the light emitting device of the present embodiment is mounted on a mounting substrate.

A light emitting device 20 of the present embodiment is provided with, as a light emitting element 12 for an excitation light source, a near-ultraviolet LED chip emitting near-ultraviolet light having a peak wavelength of 405 nm, for example.

In the light emitting element 20, a blue phosphor layer 26 containing a blue phosphor is provided on a green phosphor layer 22. For example, the blue phosphor particles are dispersed into a transparent resin layer such as a silicone resin to form the blue phosphor layer 26. As the blue phosphor, BaMgAl₁₀O₁₇:Eu is preferably used. However, the blue phosphor is not limited thereto and may be Ba₂SiS₄:Ce, Sr₅(PO₄)₃Cl:Eu, and ZnS:Ag, (Sr,Ca,Ba,Mg)₁₀(PO₄)₆Cl:Eu.

In the light emitting device 20, the near-ultraviolet light emitted from the near-ultraviolet LED chip is used as the excitation light, and the red light is emitted from the red phosphor layer 22, the green light is emitted from a green phosphor layer 24, and the blue light is emitted from the blue phosphor layer 26. Those red light, green light, and blue light are mixed, whereby the white light is emitted from the light emitting device 20.

Also in the light emitting device 20, by virtue of the provision of a filter layer 30 constituted of a two-dimensional photonic crystal or a three-dimensional photonic crystal, the reabsorption of the green light in the red phosphor layer 22 is suppressed. Accordingly, the light emitting device that suppresses the reabsorption between the phosphors and realizes the excellent light emitting efficiency can be provided.

While certain embodiments have been described, these embodiments have been presented by way of example only, and are not intended to limit the scope of the inventions. Indeed, the light emitting device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

In the embodiments, the case where the sialon-based phosphor is used as the red phosphor and the green phosphor has been described as an example. In view of suppressing the temperature quenching, it is preferable to use the sialon-based phosphor, and particularly a phosphor represented by the above formulae (1) and (2). However, the other phosphors described above may be used.

Further, in the embodiments, the case where BaMgAl₁₀O₁₇:Eu is used as the blue phosphor has been described as an example. In view of improving the efficiency, although the phosphor is preferably used, the other phosphors described above may be used.

Although sapphire has been used as an example of the transparent medium layer, the material of the transparent medium layer may be any kinds of materials such as an inorganic material and a resin as long as it is substantially transparent in a visible region at wavelength near and longer than the peak wavelength of the light emitting element (excitation element).

The resin used in the phosphor layer may be any kinds of resins as long as it is substantially transparent in a visible region at wavelength near and longer than the peak wavelength of the light emitting element (excitation element). As general resins used in the phosphor layer, a silicone resin, an epoxy resin, a polydimethylsiloxane derivative having an epoxy group, an oxetane resin, an acrylic resin, a cycloolefin resin, a urea resin, a fluorine resin, and a polyimide resin are considered.

In the embodiment, the phosphor layer and the filter layer having the plate shape have been described. However, the present invention is effective not only in the phosphor layer and the filter layer having the plate shape but also the phosphor layer and the filter layer having a dome shape and a curved plate shape.

A reflective layer that reflects, for example, red light returning toward the light emitting element may be provided separately. For example, when a heat radiating filler is dispersed in the reflective layer, a heat radiation property can be enhanced.

For example, a yellow phosphor layer may be provided as the first phosphor layer, instead of the green phosphor layer. For example, the yellow phosphor layer may be further provided between the filter layer and the green phosphor layer. A yellow phosphor emitting light of color other than red or green may be provided in the red phosphor layer or the green phosphor layer.

What is claimed is:

1. A light emitting device comprising:
a light-emitting element emitting excitation light of a first wavelength,
a first phosphor layer containing a first phosphor that converts the excitation light into first converted light of a second wavelength longer than the first wavelength;
a second phosphor layer provided between the light-emitting element and the first phosphor layer, receiving the excitation light, and containing a second phosphor that converts the excitation light into second converted light of a third wavelength longer than the second wavelength; and
a filter layer provided between the first phosphor layer and the second phosphor layer and constituted of a two-dimensional photonic crystal or a three-dimensional photonic crystal that transmits the excitation light and the second converted light and reflects the first converted light.

2. The device according to claim 1, wherein the excitation light is blue light, the first converted light is yellow light or green light, and the second converted light is red light.

3. The device according to claim 1, wherein the excitation light is near-ultraviolet light, the first converted light is yellow light or green light, and the second converted light is red light.

4. The device according to claim 1, wherein the two-dimensional photonic crystal and the three-dimensional photonic crystal have a woodpile structure, a Yablonovitch structure, or a face-centered cubic lattice structure.

5. The device according to claim 1, wherein the second phosphor is a red phosphor having the following composition (formula 1):
(M₁₋ₓ₁Euₓ₁)ₐSi_{b}AlO_{c}N_{d} (1)
where, M is an element selected from a group IA element, a group IIA element, a group IIIA element, a group IIIB element except for Al, a rare-earth element, and a group IVB element, and x1, a, b, c, and d satisfy the following relationship:
0<x1<1
0.55<a<0.95
2.0<b<3.9
0<c<0.6
4<d<5.7

6. The device according to claim 1, wherein the first phosphor is a green phosphor having the following composition (formula 2):
(M₁₋ₓ₂Euₓ₂)_{3-y}Si_{13-z}Al_{3+z}O₂₊ᵤN_{21-w} (2)
where, M′ is an element selected from a group IA element, a group IIA element, a group IIIA element, a group IIIB element except for Al, a rare-earth element, and a group IVB element, and x2, y, z, u, and w satisfy the following relationship:
0<x2<1
−0.1<y<0.3
−3<z≦1
−3<u−w≦1.5

7. The device according to claim 5, wherein the first phosphor is a green phosphor having the following composition (formula 2):
(M′₁₋ₓ₂Euₓ₂)_{3-y}Si_{13-z}Al_{3+z}O₂₊ᵤN_{21-w} (2)
where, M′ is an element selected from a group IA element, a group IIA element, a group IIIA element, a group IIIB element except for Al, a rare-earth element, and a group IVB element, and x2, y, z, u, and w satisfy the following relationship:
0<x2<1
−0.1<y<0.3
−3<z≦1
−3<u−w≦1.5

8. The device according to claim 1, wherein a plurality layers constituted of a plurality of silicon stripes are stacked to form the filter layer.

9. The device according to claim 2, wherein the reflactance of green light of the two-dimensional photonic crystal or the three-dimensional photonic crystal is not less than 90%, and the transmittance of the blue light and the red light of the two-dimensional photonic crystal or the three-dimensional photonic crystal is not less than 90%.

10. The device according to claim 1, wherein the filter layer has isotropy with respect to the transmittance and the reflectance to light.

11. The device according to claim 5, wherein the M in the formula (1) is strontium (Sr).

12. The device according to claim 6, wherein the M′ in the formula (2) is strontium (Sr).

13. The device according to claim 1, wherein a transparent medium layer is formed between the light emitting element and the second phosphor layer.

14. The device according to claim 13, wherein the transparent medium layer is sapphire.
